(19) United States
(12) Patent Application Publication
(10) Pub. No.: US 2004/0045701 A1
(43) Pub. Date: Mar. 11, 2004

(54) Radiator

(76) Inventors: Chao-Ting Chen, Taoyuan (TW); Ching-Fong Huang, Taipei (TW); Ghi-Fu Wu, Taoyuan (TW)

Correspondence Address: BIRCH STEWART KOLASCH & BIRCH, PO BOX 747, FALLS CHURCH, VA, 22040-0747, US

(21) Appl. No.: 10/403,018

(22) Filed: Apr. 1, 2003

(30) Foreign Application Priority Data
Sep. 9, 2002 (TW) 091214124

(51) Int. Cl. H05K 7/20; H01L 23/26; F28F 7/00

(52) U.S. Cl. 165/185; 165/80.3; 361/697; 361/704; 174/16.3

(57) ABSTRACT

A radiator bonding to a heat source for transmitting thermal energy includes a conductive base board and a plurality of radiation fins. The conductive base board is in contact with the heat source to perform heat transfer. The radiation fins are mounted onto the conductive base board and are segmented into a first fin section and a second fin section that are spaced from each other at a selected distance to form an airflow space with a wider upper end and a narrower lower end. Airflow generated by a radiation air fan is directly channeled to the conductive base board to perform heat exchange.

### FIELD OF THE INVENTION

The invention relates to a radiator for dispersing heat from a heat source located in an electronic device that has elements generating thermal energy during operation, such as a central processing unit (CPU).

### BACKGROUND OF THE INVENTION

A computer consists of many electronic elements, including a main board, a power supply, hard disk drives, a floppy disk drive, and an optical disk drive. These electronic elements unavoidably generate thermal energy during operation. This thermal energy must be dispersed to the surrounding environment through selected channels such as thermal conduction, thermal convection or thermal radiation to prevent the electronic elements from overheating and the resulting impact on product stability and reliability. In the computer system, the heat dissipation problem of the main processing element—the CPU—is most critical. Hence heat dissipation for the CPU is a heavily focused issue for most computer manufacturers.

With the continuous advance of processor technology, CPU operation frequency has increased to 1 GHz or more. Its heat generation power is more than 50W. If the heat generated by the CPU cannot be discharged effectively, computer performance will be negatively impacted and the computer's service life will be shortened. Thus heat dissipation becomes more critical when the computer processing frequency increases.

Present heat dissipation devices for CPUs are mostly radiators and radiation air fans. The radiator is made from metal and includes a base and a plurality of radiation fins mounted onto the base. The base is mounted onto and in contact with the CPU. Thermal energy generated by the CPU during operation is transmitted through the base to the radiation fins. The radiation air fan is located above the radiation air fins to generate airflow to flow into the radiation fins. Heat exchange occurs between the airflow and the high temperature radiation fins to carry away the thermal energy from the radiator and to reduce the temperature of the CPU to achieve the object of heat dissipation.

In the past, radiators were mostly made from aluminum because of its lower thermal resistance, lighter weight and lower cost. However, with the continual increase of CPU operation frequency, effectiveness of the radiator also must increase. Thus some vendors are trying to make radiators from copper.

The coefficient of heat transmission of copper is 1.8 times that of aluminum, and the density of copper is three times that of aluminum. With a radiation fin of the same size and volume, the weight of copper is three times that of aluminum. Hence although the radiator made from copper has better heat conduction than the radiator made from aluminum, its weight is much greater. The main board that holds the CPU has to withstand a greater weight when a copper radiator is used. Therefore to utilize the advantage of better heat conduction of the copper radiator, the loading of the main board is an issue that must be properly addressed.

Selection of radiation materials has to consider material properties. How to improve radiation effectiveness through structural design is an object of the invention. Most radiation fins now being used on radiators are mounted vertically onto the base of the radiators. Thermal energy of the CPU is transmitted through the base to the radiation fins. Hence the temperature at the base is the highest in the entire radiator. However, lower temperature airflow generated by the air fan is channeled from top to bottom in the radiation fins. After heat exchange with the top ends of the radiation fins, the temperature of the airflow is higher, and the airflow of higher temperature is directed downwards. As a result, the bottom of the radiation fins and the base that have higher temperatures cannot receive the lower temperature airflow. Such a design cannot effectively reduce the temperature of the higher temperature portions of the radiator.

### SUMMARY OF THE INVENTION

In view of the aforesaid problems, the primary object of the invention is to provide a radiator that can channel cooling airflow to the higher temperature portions of the radiator to improve radiation efficiency. The radiator of the invention is adopted for dissipating heat of a heat source. The radiator includes a conductive base board and a plurality of radiation fins. The radiation fins are segmented to a first fin section and a second fin section. The first fin section and the second fin section have corresponding sides to form an acute angle with the bottom side. Hence there is an airflow space formed between the first fin section and the second fin section, and the airflow space has a wider upper end and a narrower lower end. By means of such a design, airflow generated by the air fan can directly flow to the conductive base board to enable a portion of the airflow to perform heat exchange directly with the bottom section of the radiation fins and the conductive base board, thereby heat exchange efficiency can be improved.

In addition, the airflow space of the wide upper end and the narrow lower end in the radiator of the invention enables the air fan to generate a pressure boosting effect to discharge airflow more smoothly.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a perspective view of the radiator of the invention.

FIG. 2 is a side view of the radiator of the invention.

FIG. 3 is a schematic view of the radiator of the invention in use.

FIG. 4 is a schematic view of the airflow path of the invention.

FIG. 5 is a schematic view of another embodiment of the radiator of the invention.

FIG. 6 is a schematic view of the assembly of a second embodiment of the invention.

FIG. 7 is an exploded view of the second embodiment of the invention.

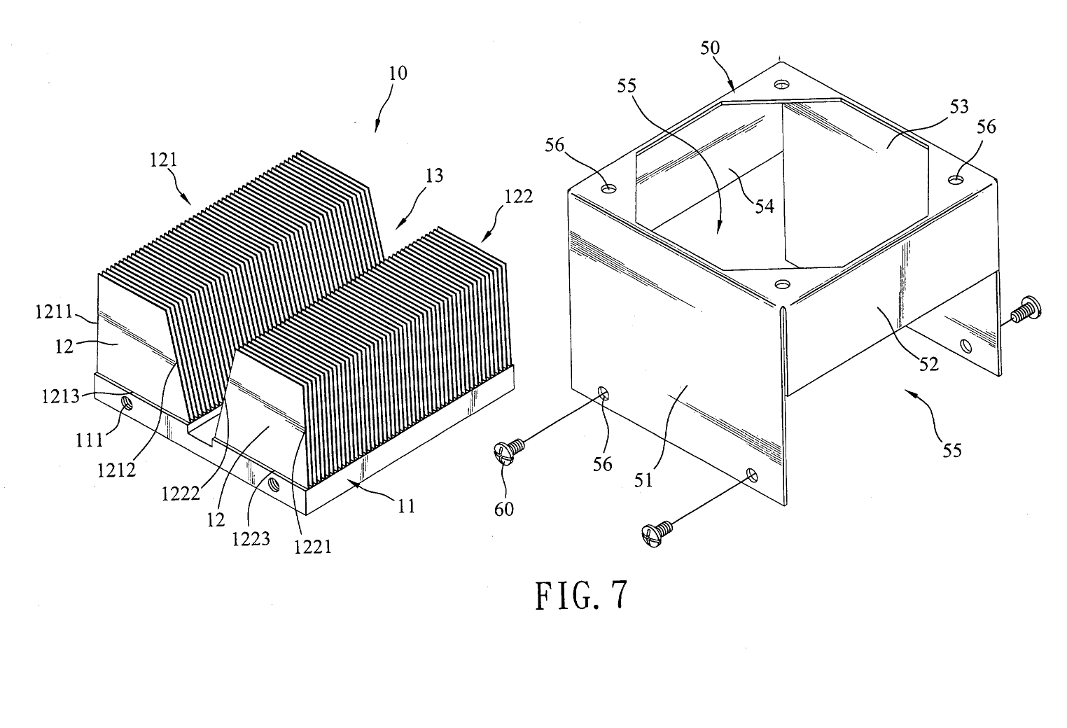

FIG. 8 is a perspective view of the second embodiment of the invention in use.

FIG. 9 is a schematic view of the airflow path in the radiation module of the invention.

### DESCRIPTION OF THE PREFERRED EMBODIMENTS

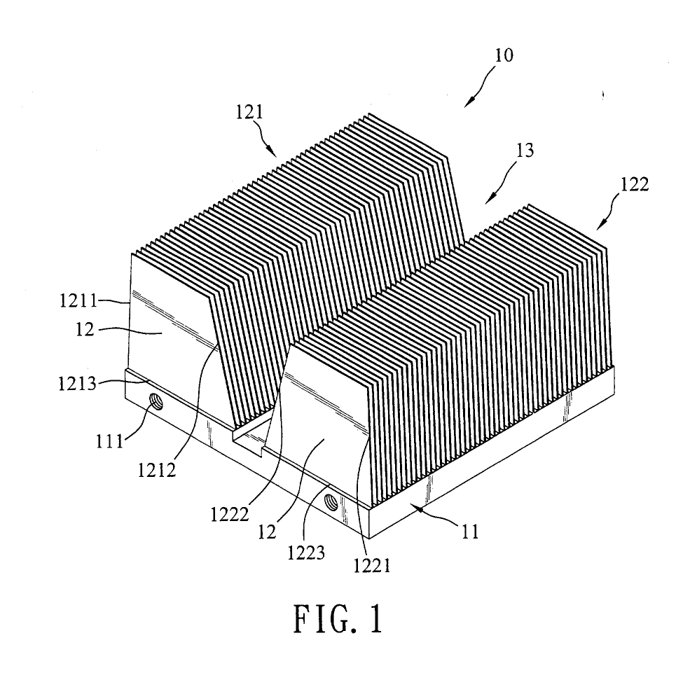

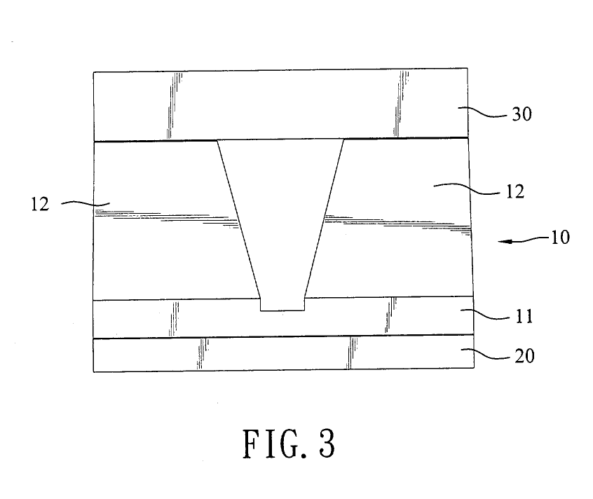

The invention aims at providing a radiator to make contact with a heat source to perform heat transfer and through a radiation air fan located above the radiator to deliver cooling air to perform heat exchange with the radiator, to thereby disperse heat from the heat source. The heat source is mainly the CPU of the computer system. However, the embodiments according to the invention are not limited to a CPU. They can also be used on other electronic elements that generate thermal energy during operation. The following embodiments are based on a CPU for explanation. Refer to FIG. 1 for a first embodiment of the invention. The radiator 10 is bonded to a CPU 20 (also shown in FIG. 3) to conduct thermal energy from the CPU to prevent the CPU from overheating and becoming damaged. The radiator 10 is made from metal of a high coefficient of heat transmission such as aluminum, copper or the like. It consists of a conductive base board 11 and a plurality of radiation fins 12. The radiation fins 12 include a first fin section 121 and a second fin section 122. The conductive base board 11 is a rectangular member (other shapes may be adopted) matching the shape of the CPU 20. It has a flat bottom surface to bond to and make contact with the CPU 20. In actual fabrication a layer of heat insulation adhesive (not shown in the drawing) is coated between the conductive base board 11 and the CPU 20 to ensure that the conductive base board 11 and the CPU 20 are in contact in the optimal manner to increase heat transmission efficiency. The radiation fins 12 are vertically mounted onto the top surface of the conductive base board 11. The bonding of the radiation fins 12 to the conductive base board 11 may be accomplished by means of adhesive or machining such as cutting, extrusion or the like. The first fin section 121 and the second fin section 122 are located on two sides of the conductive base board 11 and are spaced from each other at a selected distance. The first fin section 121 and the second fin section 122 have respectively an outer side 1211 and 1221 that are aligned with the outer side of the conductive base board 11. The first fin section 121 and the second fin section 122 further have respectively an inner side 1212 and 1222 spaced from each other at a selected distance to form an airflow space 13.

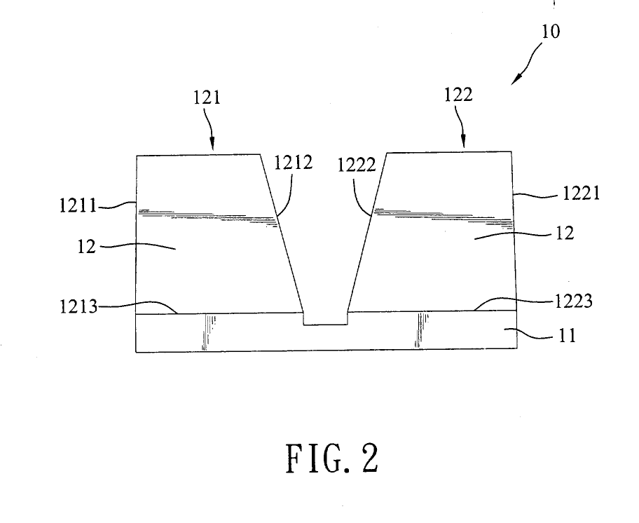

Referring to FIG. 2, the inner side 1212 and a bottom side 1213 of the first fin section 121 form an acute angle θ (the second fin section 122 is symmetrical to the first fin section 121) such that the first fin section 121 is narrower at the upper end and becomes gradually wider at the lower end to make the inner side 1212 a slope. The second fin section 122 is formed like the first fin section 121 in a symmetrical fashion. Thus the airflow space 13 formed between the first fin section 121 and the second fin section 122 has a wider upper end and a narrower lower end.

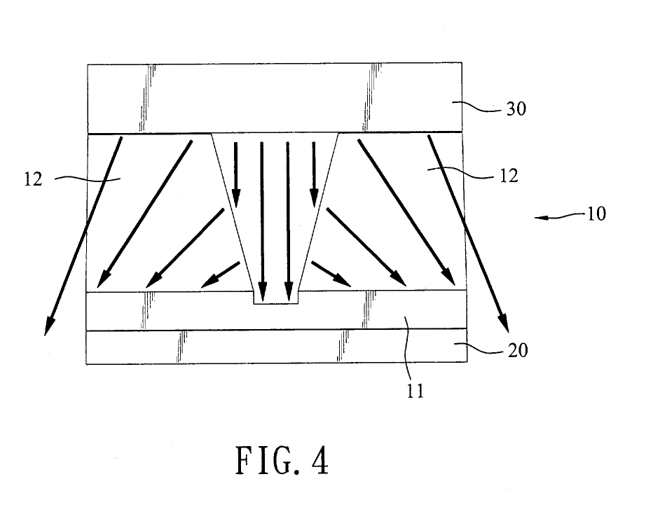

Referring to GIG. 3, when the invention is in use, the radiator 10 is bonded to the CPU 20, and a radiation air fan 30 is mounted above the radiator 10. The conductive base board 11 of the radiator 10 is in contact with the CPU 20 so that thermal energy generated by the CPU 20 during operation is transmitted to the conductive base board 11 and to the radiation fins 12. The radiation air fan 30 rotates and generates downward airflow, which has a lower temperature than the radiator 10. Thus heat exchange occurs between the airflow and the radiator 10. The heated air is discharged through two sides of the radiation fins 12 to dissipate heat from the CPU 20. Referring to FIG. 4, the main difference between the invention and the conventional technique is that in the latter, air flows from the upper portions of the radiation fins 12 to the lower portions and the conductive base board 11. As the higher temperature portion of the radiator 10 is located on the conductive base board 11 and the bottom section of the radiation fins 12 close to the CPU 20, the conventional design cannot effectively and directly channel the airflow to the bottom section of the radiation fins 12 or the conductive base board 11. Therefore radiation efficiency is not desirable.

The airflow space 13 of the invention has a wider upper end and a narrower lower end, thus enabling the airflow generated by the radiation air fan 30 to be directly channeled to the bottom section of the air fins 12 or the conductive base board 11 to perform heat exchange with the portions that are of a higher temperature. Thus the heat dissipation problem at the higher temperature portions of the radiator 10 can be resolved effectively and total radiation efficiency is improved.

In addition, the design of airflow space 13 that is wider at the top and narrower at the bottom also has the effect of guiding and compressing the airflow. By compressing airflow to a smaller volume and a greater pressure, the temperature in the surrounding fluid field may be reduced to carry away the thermal energy accumulated on the conductive base board 11.

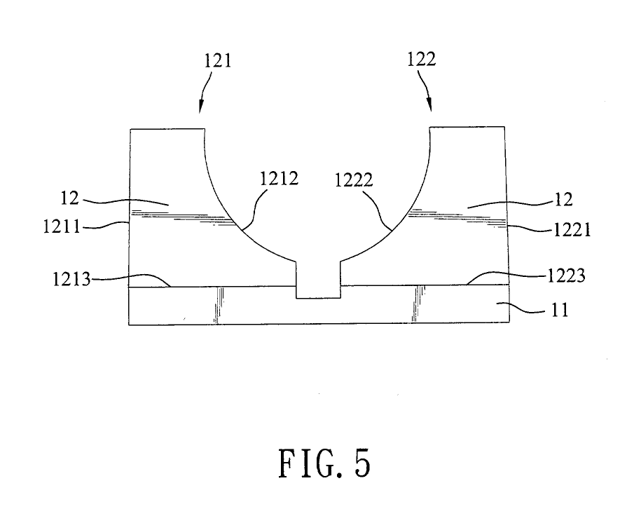

Refer to FIG. 5 for another embodiment of the invention. The radiator 10 of the invention aims at providing an airflow space that is wider at the top and narrower at the bottom to directly channel airflow generated by the radiation air fan 30 to the bottom section of the radiation fins 12 and the conductive base board 11. Based on this principle, the inner sides 1212 and 1222 of the first fin section 121 and the second fin section 122 may be formed in arched shapes to achieve the object of the invention.

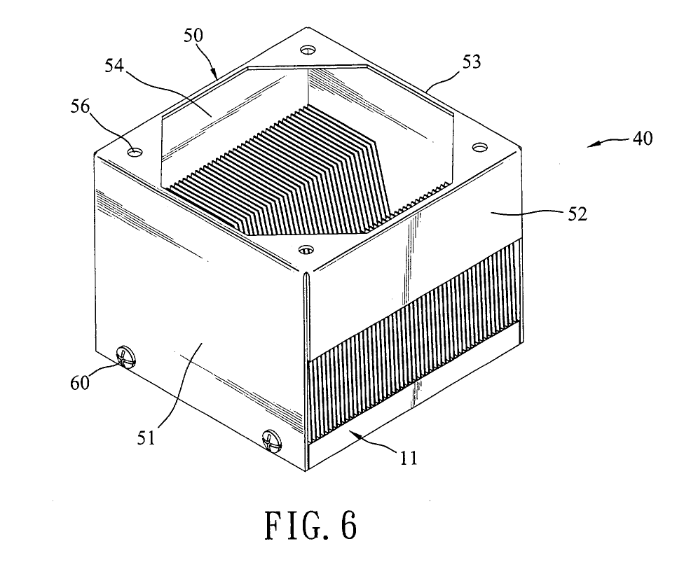

Refer to FIG. 6 for a second embodiment of the invention. A radiation module 40 includes an air mask 50 to surround the radiator 10 described above. The air mask 50 is spaced from the radiator 10 at a desired height. The air mask 50 is fastened to the conductive base board 11 by means of fastening elements 60 (with corresponding fastening holes 111 formed on the conductive base board 11). The spaced air mask 50 with a desired height enables the airflow channeled from the air fan 30 located above to generate an air mask effect to reduce airflow friction, and through air pressure, to channel the airflow to the conductive base board 11. Thus air reflux resulting from airflow directly hitting the radiation fins 12 and flowing backwards to the air fan 30 may be avoided.

The radiator 10 of the second embodiment is the same as that of the first embodiment, so details are omitted. The air mask 50 is constructed to match and encase the radiator 10. It is substantially a rectangular frame having two long sides 51 and 53, and two short sides 52 and 54. The long sides 51 and 53 correspond to the lateral sides of the radiation fins 12, while the short sides 52 and 54 correspond to the spaced portions of the radiation fins 12. The height of the short sides 52 and 54 just covers the top rim of the radiation fins 12 to enable airflow to be discharged through the interval space of the radiation fins 12. The lower sections of the short sides 52 and 54 form two air outlets 55. The top side of the air mask 50 has four fastening apertures 56 formed on the periphery thereof for fastening the air fan 30 and enabling the air fan 30 to provide airflow for heat dissipation.

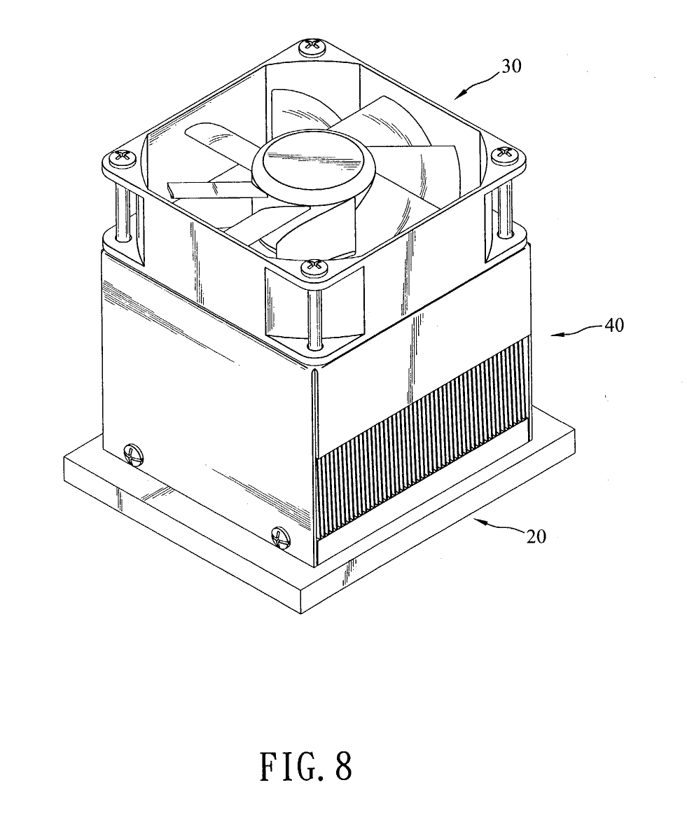

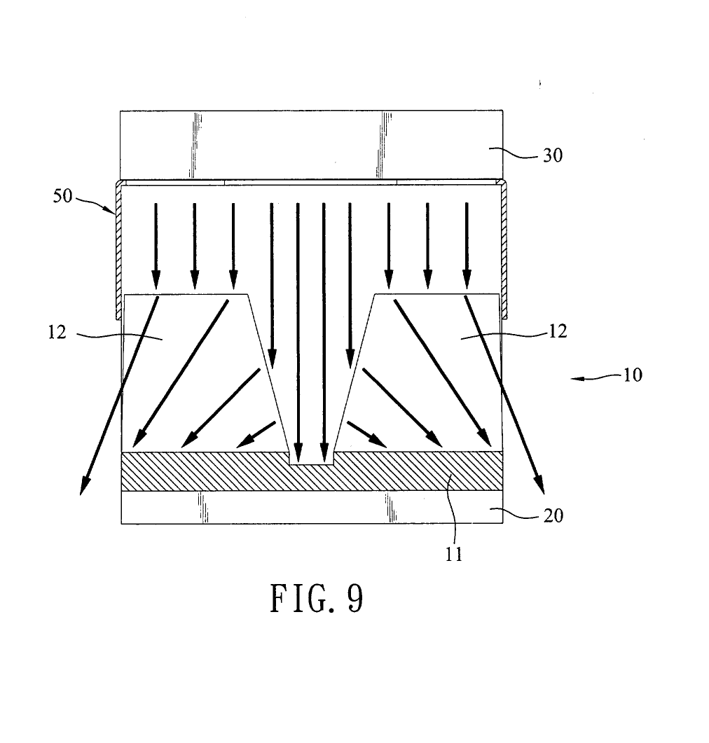

Refer to FIGS. 8 and 9 for the application of the radiation module 40. First, the radiator 10 is bonded to the CPU 20. Next, the air mask 50 is disposed to encase the radiator 10. Then the air fan 30 is fastened to the top end of the air mask 50 with the air fan 30 spaced from the radiation fins 12 at a selected distance. Then wind generated by the air fan 30 can be channeled directly to the conductive base board 11 to perform heat exchange and effectively increase radiation efficiency.

In summary, the invention can achieve the following effects:

1. The radiator has an airflow space that is wider at the top end and narrower at the bottom end, thus wind may be channeled smoothly to the bottom section of the radiation fins and conductive base board to increase radiation efficiency.

2. The design of the airflow space, being wider at the top end and narrower at the bottom end, increases pressure due to gradually narrowing space. Therefore airflow in the surrounding fluid fields may have a lower temperature to carry away thermal energy accumulated on the conductive base board and can prevent the CPU from overheating and being damaged.

3. The design of the airflow space can increase radiation efficiency of the entire radiator. If the radiator is made from aluminum, the design enables it to achieve the same performance as a radiator made from copper. The load on the CPU or main board resulting from the radiator may be reduced. If the radiator is made from copper, radiation effectiveness can be greatly improved to meet the heat dissipation requirements of high speed operation.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments which do not depart from the spirit and scope of the invention.

What is claimed is:

1. A radiator bonding to a heat source to perform heat transfer with the heat source, comprising:
a conductive base board bonding to the heat source; and
a plurality of radiation fins spaced from one other and vertically mounted onto the conductive base board including a first fin section and a second fin section that are spaced from each other for a selected distance and located on two sides of the conductive base board, the first fin section and the second fins section having respectively an inner side spaced from each other for a selected distance to form an airflow space which has a wider upper end and a narrower lower end.

2. The radiator of claim 1, wherein the radiator is made from aluminum.

3. The radiator of claim 1, wherein the radiator is made from copper

4. The radiator of claim 1, wherein the heat source is a central processing unit.

5. The radiator of claim 1, wherein the inner side of the first fin section and the second fin section form an acute angle with a bottom side of the first fin section and the second fin section such that the inner side is a slope extending gradually wider from the upper end to the lower end to form the airflow space of a wider upper end and a narrower lower end.

6. The radiator of claim 1, wherein the inner side of the first fin section and the second fin section is an arched line extending gradually wider from the lower end to the upper end.

7. A radiation module bonding to a heat source and coupling with an air fan to perform heat exchange with the heat source, comprising:
a conductive base board bonding to the heat source;
a plurality of radiation fins spaced from one other and vertically mounted onto the conductive base board including a first fin section and a second fin section that are spaced from each other for a selected distance and located on two sides of the conductive base board, the first fin section and the second fins section having respectively an inner side spaced from each other for a selected distance to form an airflow space which has a wider upper end and a narrower lower end; and
an air mask encasing the conductive base board and the radiation fins and having a top end fastening to the air fan with the top end spacing from the radiation fins for a selected distance, the air mask having two air outlets corresponding to two sides of the radiation fins that are spaced.

8. The radiation module of claim 7, wherein the air mask has a plurality of fastening apertures for fastening the air fan to the air mask.

9. The radiation module of claim 7, wherein the air mask has a plurality of fastening apertures and the conductive base board has fastening holes corresponding to the fastening apertures for fastening the air mask to the conductive base board through fastening elements.

10. The radiation module of claim 7, wherein the heat source is a central processing unit.

11. The radiation module of claim 7, wherein the inner side of the first fin section and the second fin section form an acute angle with a bottom side of the first fin section and the second fin section such that the inner side is a slope extending gradually wider from the upper end to the lower end to form the airflow space of a wider upper end and a narrower lower end.

12. The radiation module of claim 7, wherein the inner side of the first fin section and the second fin section is an arched line extending gradually wider from the lower end to the upper end.
